(19) United States
(12) Patent Application Publication
(10) Pub. No.: US 2005/0249256 A1
(43) Pub. Date: Nov. 10, 2005

(54) WAVELENGTH SWITCHABLE SEMICONDUCTOR LASER

(75) Inventor: Jian-Jun He, Ottawa (CA)

Correspondence Address: LIGHTIP TECHNOLOGIES, INC., 40 COLLEGE CIRCLE, OTTAWA, ON, K1K-4R8, CA

(73) Assignee: LIGHTIP TECHNOLOGIES INC., Ottawa (CA)

(21) Appl. No.: 10/908,362

(22) Filed: May 9, 2005

Related U.S. Application Data
(60) Provisional application No. 60/569,080, filed on May 10, 2004.

(51) Int. Cl. H01S 5/00

(52) U.S. Cl. 372/50.1; 372/20

(57) ABSTRACT

A monolithically integrated wavelength switchable laser comprises three coupled Fabry-Perot cavities. The length and consequently the free spectral range of the first cavity are designed such that the resonant peaks correspond substantially to a set of discrete operating wavelengths separated by a constant channel spacing. The second cavity has a slightly different length so that only one resonant peak coincides with one of the resonant peaks of the first cavity over the spectral window of the material gain. The lasing action occurs at the common resonant wavelength. The two cavities are coupled through a third short cavity that produces a certain coupling loss and phase relationship between the first and the second cavities in order to achieve an optimal mode selectivity of the combined cavity laser. In operation, both the first and the second cavities are forward biased to provide optical gains for the laser action. The second cavity is tuned by varying the refractive index of at least a portion of the waveguide within the cavity through an electrical means, resulting in wavelength switching of the laser among the set of discrete operating wavelengths as determined by the first cavity.

### RELATED APPLICATIONS

This application claims benefit from U.S. Provisional Patent Application Ser. No. 60/569,080, filed on May 10, 2004, entitled “Wavelength switchable laser”.

### FIELD OF THE INVENTION

This invention relates generally to a semiconductor laser, and more particularly to a monolithically integrated wavelength-switchable semiconductor laser.

### BACKGROUND OF THE INVENTION

Widely tunable lasers are of great interest for both long-haul and metropolitan optical networks. Besides their use for source sparing with the advantages of reduced inventory and cost reduction, they open the possibility of new system architectures with more efficient and more flexible network management. For example, the combination of tunable lasers with passive wavelength routers can provide large format-independent space switches and reconfigurable optical add/drop functions.

Monolithically integrated semiconductor tunable lasers offer many advantages over external-cavity tunable lasers assembled from discrete components. They are compact, low-cost, and more reliable as they contain no moving parts. A conventional monolithic tunable laser usually comprises a multi-electrode structure for continuous tuning. FIG. 1 shows a prior-art example of a semiconductor tunable laser consisting of a distributed Bragg reflector (DBR) grating, an active gain section, and a phase-shift region. An electrode for electrical control is deposited on top of each of the three sections. When the reflection peak wavelength of the DBR grating is tuned by injecting current or applying an electrical voltage, the phase shift region must be adjusted simultaneously in order to prevent the laser from hopping from one mode to another as the wavelength changes.

A more sophisticated tunable laser with a wider tuning range and improved performances was described by V. Jarayman, Z. M. Chuang, and L. A. Coldren, in an article entitled “Theory, design, and performance of extended tuning range semiconductor lasers with sampled gratings”, IEEE J. Quantum Electron. Vol. 29, pp. 1824-1834, 1993. It comprises of four electrodes controlling two sampled grating distributed Bragg reflectors, a phase-shift region and a gain section. The wavelength tuning requires complex electronic circuits with multidimensional current control algorithms and look-up tables. Such complexity reduces the fabrication yield and increases the cost, and also opens the questions about the manufacturability and long term stability of the devices. This is one of the reasons for the fact that monolithic widely tunable lasers are still relatively immature today and have not been widely deployed in practical systems.

For many applications, it is not necessary to tune the laser wavelength continuously. Rather, it is only required that the laser can be set to any discrete wavelength channel, e.g. as defined by the ITU (International Telecommunication Union). Such applications include linecard sparing, wavelength routing and optical add/drop. Key requirements for such wavelength switchable lasers are: 1) an accurate match of the discrete operating wavelengths with the predefined wavelength channels (e.g. ITU grid); 2) simple and reliable control for the switching between various wavelength channels; 3) fast switching speed; 4) low crosstalk; and 5) easy to fabricate and low cost.

It is an object of the present invention to provide a monolithically integrated semiconductor laser that is wavelength-switchable and which satisfies all above requirements.

### SUMMARY OF THE INVENTION

In accordance with the invention, there is provided, a monolithically integrated wavelength switchable laser comprising:
a first active optical cavity consisting of a first active waveguide bounded by two partially reflecting elements,
a second active optical cavity consisting of a second active waveguide bounded by two partially reflecting elements, said second active waveguide having a slightly different length than the first active waveguide,
a passive optical cavity placed between the first and the second active optical cavities, said passive optical cavity being coupled with each of the first and the second active optical cavity through a shared partially reflecting element,
whereas each of the first and the second active waveguides is sandwiched between at least a pair of electrodes for injecting current to provide optical gain, with the current injected into at least a portion of the second active waveguide being variable in order to change its refractive index and consequently to switch the laser wavelength between channels as determined by the resonant wavelengths of the first active optical cavity, and whereas the passive optical cavity introduces a certain optical loss in order to produce single-mode operation of the laser.

### BRIEF DESCRIPTION OF THE DRAWINGS

FIG. 1 is a prior art semiconductor tunable laser consisting of a DBR grating, an active gain section, and a phase-shift region.

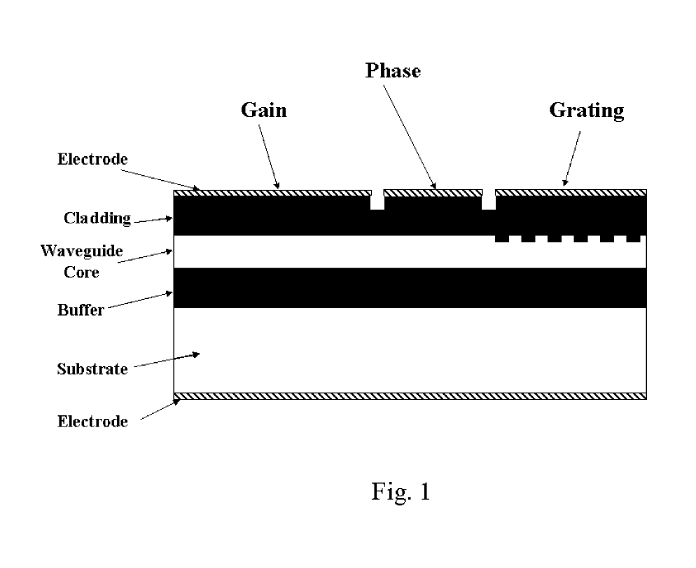

FIG. 2 is an integrated wavelength switchable laser in accordance with the present invention.

FIG. 3 is a schematic diagram showing the relationships between the two sets of resonant peaks of the fixed gain cavity and the channel selector cavity, the transmission function of the coupling cavity and the material gain spectrum.

FIG. 4 is the reflectivity and transmission coefficients of an air gap as a function of the gap size at 1550 nm wavelength.

FIG. 5 is the reflectivity spectra for air gaps of sizes equal to λ/4, 3λ/4, 5λ/4, 7λ/4, 9λ/4, 11λ/4, and 13λ/4.

FIG. 6 is the reflectivity spectrum of the reflector comprising the coupling cavity and the channel selector cavity as seen by the fixed cavity, for an example case where the coupling cavity has a single-pass loss value of 4.9 dB.

FIG. 7 is the calculated small signal gain for the case where both the fixed gain cavity and the channel selector are pumped close to the lasing threshold of the combined cavity.

FIG. 8 is the reflectivity spectra of the reflector comprising the coupling cavity and the channel selector cavity for different coupling cavity losses of 1.23 dB (a) and 12.3 dB (b).

FIG. 9 is the thresholds of the lasing modes for different coupling cavity losses of 0, 1.23 dB, 2.46 dB, 4.9 dB, 7.4 dB, and 12.3 dB.

FIG. 10 is the relative threshold difference between adjacent (a) and distant (b) modes as a function of the coupling cavity loss.

### DETAILED DESCRIPTION

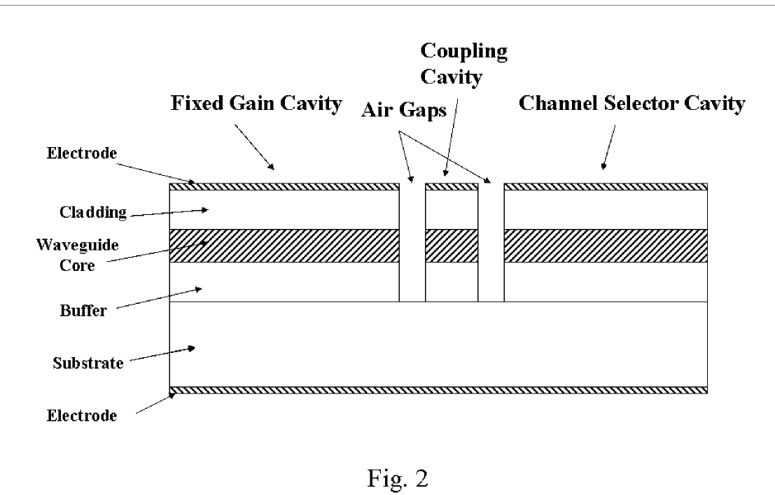

FIG. 2 illustrates a monolithic wavelength switchable laser in accordance with the present invention. It consists of three Fabry-Perot cavities separated by etched air gaps, two of which are electrically pumped to produce optical gain for the laser while the coupling cavity in the middle is generally absorptive to improve single-mode characteristics. Each of the two gain cavities is formed by a cleaved facet on one end and an air gap with vertically etched sidewalls on the other. In order for the air gap to act as a high-reflectivity mirror, the gap size is to be substantially equal to an odd-integer multiple of quarter-wavelength, i.e., λ/4, 3λ/4, 5λ/4, . . . etc. The optical path length of the coupling cavity is substantially equal to a multiple of half-wavelength, so that the two gain cavities are in phase at the resonance conditions. In operation, one of the gain cavities is injected with an essentially fixed current (referred as fixed gain cavity), while the current injected in the other cavity (referred as channel selector cavity) is varied in order to switch the laser wavelength. The coupling cavity can be optionally reverse-biased to provide an adjustable loss in order to obtain optimal mode selectivity for the wavelength switchable laser.

The waveguide structure generally consists of a buffer layer, waveguide core layer that also provides gain when electrically pumped, and upper cladding layer, deposited on a substrate. An electrode layer is deposited on the top surface. The backside of the substrate is also deposited with another metal electrode layer as a ground plane. The electrodes provide a means for injecting current to produce gains, and in the case of the channel selector, also to change the refractive index of the waveguide. Preferably the waveguide core layer comprises multiple quantum wells as in conventional laser structures and the layers are appropriately doped. In the transverse direction, standard ridge or rib waveguides are formed to laterally confine the optical mode.

The general concept of the coupled-cavity laser was investigated in early 1980's. It is realized either by an etched groove inside a cleaved Fabry-Perot laser, as described in a paper entitled “Monolithic two-section GaInAsP/InP active-optical-resonator devices formed by reactive-ion-etching”, by L. A. Coldren et al, Appl. Phys. Lett., vol. 38, pp. 315˜317, 1981, or in a cleaved-coupled-cavity structure, as described in a paper entitled “The cleaved-coupled-cavity (C³) laser”, by W. T. Tsang, Semiconductors and Semimetals, vol. 22, p. 257, 1985. However, the performance of the prior-art coupled-cavity lasers especially in terms of mode selectivity was not satisfactory, which results in discontinued interest for practical applications. The present invention provides special designs including a coupling cavity with predetermined operating conditions for significantly improved performance.

In accordance with the present invention, the length of the fixed gain cavity is chosen so that its free spectral range matches the spacing of the operating wavelength grid, an example being the widely used wavelength grid defined by ITU. The free spectral range in frequency is determined by

$$Δ f = \frac{c}{2 {n}_{8} L} \qquad ( 1 )$$

where c is the light velocity in vacuum, n_{g} the effective group refractive index of the waveguide, and L the cavity length.

Similarly, the free spectral range Δf′ of the second gain cavity (i.e. the channel selector) is determined by

$$Δ {f}^{′} = \frac{c}{2 {n}_{8}^{′} {L}^{′}} \qquad ( 2 )$$

where n′_{g} and L′ are the effective group refractive index and the length of the channel selector cavity.

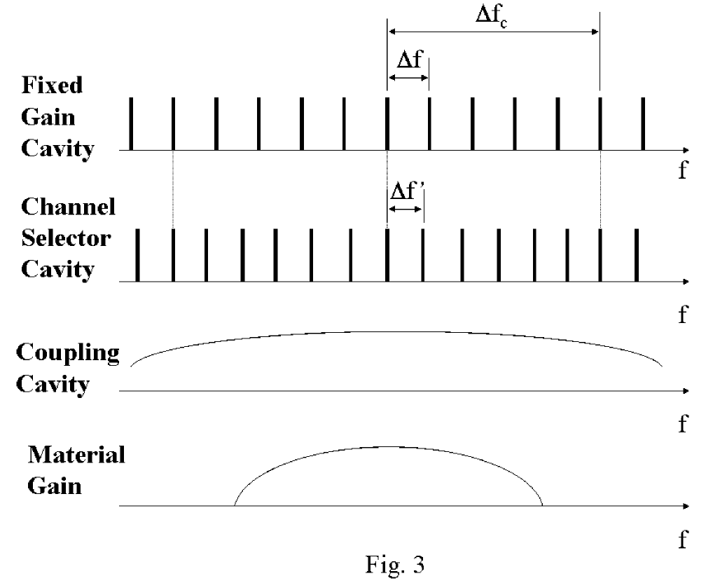

The free spectral range Δf′ of the channel selector cavity is chosen to be slightly different than Δf so that only one resonant peak coincides with one of the resonant peaks of the fixed gain cavity over the spectral gain window, as shown in FIG. 3. The distance between two aligned resonant peaks, which corresponds to the free spectral range of the combined cavity, is determined by

$$Δ {f}_{c} = \frac{Δ f Δ {f}^{′}}{\vert Δ f - Δ {f}^{′} \vert} \qquad ( 3 )$$

In order not to have two wavelengths lasing simultaneously, Δf_{c} should generally be larger than the spectral width of the material gain window.

The resonant frequencies of the gain cavity and the channel selector are determined respectively by

$$\begin{matrix}f = \frac{m c}{2 nL} & ( 4 a ) \\ {f}^{′} = \frac{{m }^{′} c}{2 {n}^{′} {L}^{′}} & ( 4 b )\end{matrix}$$

where m and m′ are integers, n and n′ the averaged effective refractive index of the waveguide within the respective cavity, L and L′ the cavity lengths. The frequency of the channel selector can be tuned by varying the effective index n′. The rate of the tuning is determined by

$$\frac{δ {f}^{′}}{ {f}^{′}} = - \frac{δ {n}^{′}}{ {n}^{′}} \qquad ( 5 )$$

Since the laser frequency is determined by the resonant peak of the fixed gain cavity that coincides with a peak of the channel selector cavity, a shift of |Δf−Δf′| in the resonant peaks of the channel selector cavity results in a jump of a channel in the laser frequency. Therefore, the change of the laser frequency with the refractive index variation is amplified by a factor of Δf/|Δf−Δf′|, i.e.,

$$δ f = \frac{Δ f}{\vert Δ f - Δ {f}^{′} \vert} δ {f}^{′} \qquad ( 6 )$$

The increased tuning range is one of the advantages of the device of the present invention. Consider an example in which Δf=100 GHz, and Δf′=98 GHz, the range of the laser frequency variation is increased by a factor of 50 with respect to what can be achieved by the index variation directly. For this numerical example, assuming the effective group refractive index of the waveguide is 3.5, the lengths of the fixed gain cavity and the channel selector cavity are L=428.5 μm and L′=437.4 μm, respectively. The total device length is comparable to conventional DFB or FP lasers.

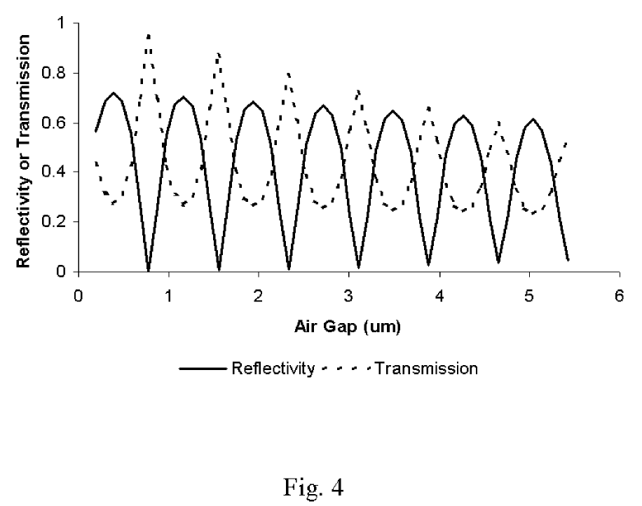

For the air gap to act as a high-reflectivity mirror, the gap size must be substantially equal to an odd-integer multiple of the quarter-wavelength, i.e., λ/4, 3λ/4, 5λ/4, . . . etc. FIG. 4 shows the reflectivity and transmission coefficient of the air gap as a function of the gap size at 1550 nm wavelength. If the gap size is equal to an even-integer multiple of the quarter-wavelength (i.e. λ/2, λ, 3λ/2, . . . etc) and the optical loss of the gap due to beam divergence is low, its reflectivity would be almost negligible.

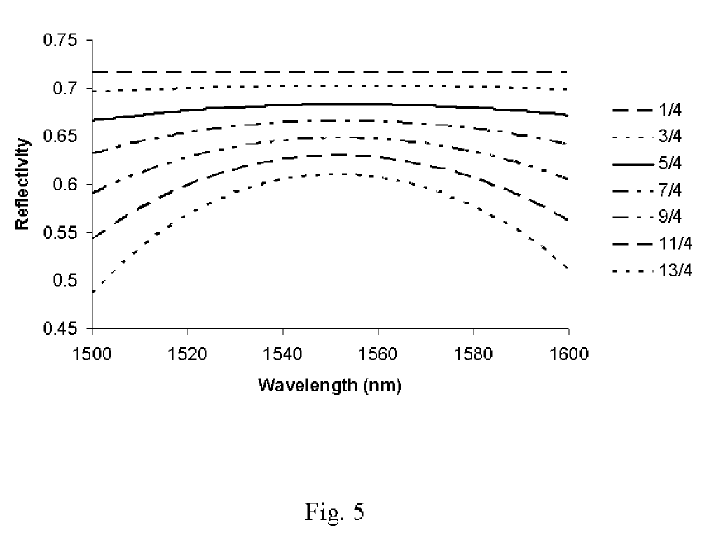

Theoretically, the best performance of the reflector is obtained with the smallest air gap, i.e., λ/4. This is for two reasons: 1) the peak reflectivity decreases as the gap size increases, because the loss increases due to beam divergence at the unguided air gap, as can be seen in FIG. 4; and 2) when the air gap is equal to pλ/4 (p is an odd integer) for a central wavelength, the deviation from this condition increases for edge channels when p is large, which increases the reflectivity non-uniformity of the air gap and consequently the performance non-uniformity across different channels, as can be seen in FIG. 5, which shows the reflectivity as a function of wavelength for air gap sizes of λ/4, 3λ/4, 5λ/4, . . . and 13λ/4. On the other hand, the fabrication becomes more challenging as the gap size decreases, since a λ/4 gap is only 0.3875 μm for 1550 nm wavelength. A 5λ/4 to 9λ/4 gap, corresponding to a size of 1.94 μm to 3.49 μm, can be a good compromise. The error tolerance on the gap should be in the order of ±0.1 μm for InP based material system, regardless of the gap size. This is achievable with current state of the art fabrication technologies.

The coupling cavity in the middle of the device has a very short length and is operated in the absorption regime. The optical path length of the coupling cavity is substantially equal to a multiple of half-wavelength, i.e. n″L″=m″λ/2, where m″ is a small integer. This condition ensures that the fixed gain cavity and the channel selector cavity are in phase and their resonance is constructive. Because of its short length, it has a broad filter function that is substantially wavelength independent over the operating wavelength range. The role of this coupling cavity is to introduce a certain amount of loss so that the fixed gain cavity and the channel selector cavity have an optimal amount of coupling. As will be shown later, this is very important for obtaining optimal mode selectivity for the wavelength switchable laser.

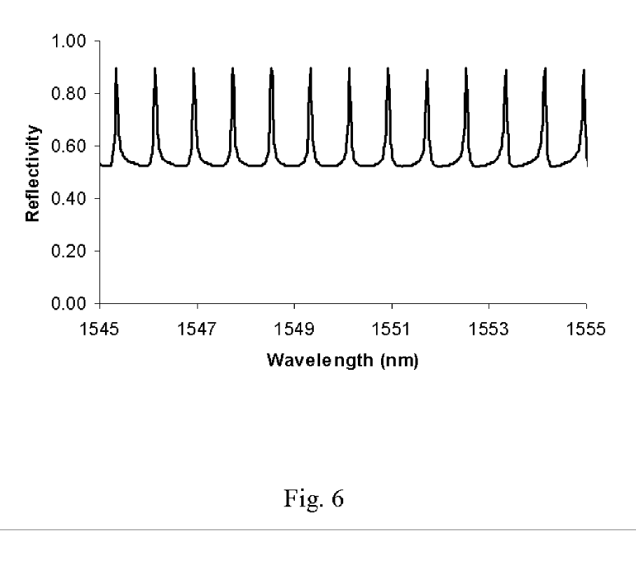

To analyze the complex-structure laser, we can consider one of the Fabry-Perot cavities (e.g. the fixed gain cavity) as the main laser cavity and include the other cavities (i.e. the channel selector cavity and the coupling cavity) in one of the reflectors of the main cavity. Consider an example structure where L=428.5 μm, L′=437.4 μm, L″=2 μm, and the size of the air gaps is 1.94 μm (5λ/4), and assume the gain coefficients of the fixed gain cavity and the channel selector cavity are identical (i.e. g′=g″=g). If the loss of the coupling cavity is 4.9 dB (corresponding to an absorption coefficient of α=5676 cm⁻¹), the calculated lasing threshold of the combined structure is gₜₕ=14.6 cm⁻¹. FIG. 6 shows the reflectivity spectrum of the reflector comprising the coupling cavity and the channel selector cavity as seen by the fixed gain cavity. It features periodical maxima, similar to what can be obtained with a sampled DBR grating (but without the fabrication complexity and long device length associated with it). The wavelengths corresponding to the reflectivity maxima are determined by Eq. (4b) and the distance between the reflectivity peaks is determined by Eq. (2).

In addition to be at the reflectivity peak of the spectrum, the lasing wavelength must also satisfy the resonance condition of the fixed gain cavity, which is determined by Eq. (4a). When the channel selector is tuned so that one of the reflectivity peaks coincides with a resonant wavelength of the fixed gain cavity, the lasing action occurs at this wavelength.

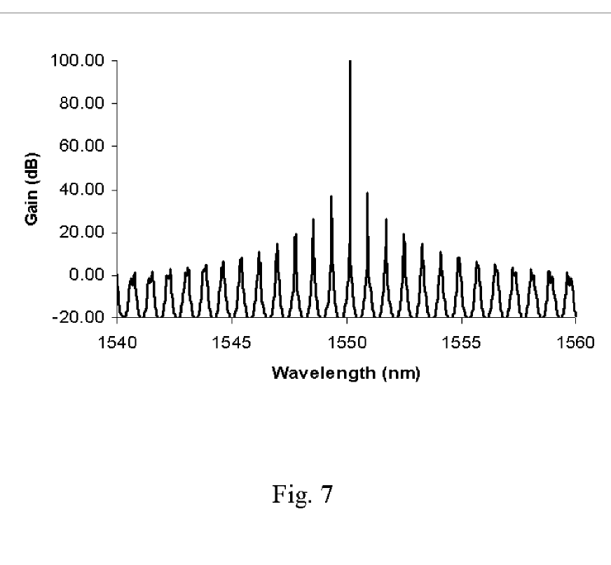

To demonstrate the wavelength selectivity of the coupled cavity laser of the present invention, we calculated the small-signal gain of the structure with an incident light coupled from the cleaved facet of the fixed gain cavity, using the transfer matrix method. FIG. 7 shows the calculated small signal gain for the case where both the fixed gain cavity and the channel selector cavity are pumped at the lasing threshold of the combined cavity with a gain coefficient of 14.6 cm⁻¹. The refractive indices of both the fixed gain cavity and the channel selector are 3.5. The lasing wavelength is at 1550.12 nm. We can see that a large side-mode suppression ratio (SMSR) can be achieved.

In the above example, the required refractive index change for shifting the wavelength by one channel at 100 GHz channel spacing is 3.7×10⁻⁵. The total required index change for covering 40 channel over entire C-band is only 1.48×10⁻³, or 0.042%, which can be achieved by either carrier injection or reverse-biased electro-optic effect.

By nature of the design, the wavelength tuning of the coupled-cavity laser of the present invention is digital rather than continuous. If the refractive index is tuned to intermediate values between the setting points of two adjacent modes (i.e. channels), a poor SMSR rather than a wavelength error occurs. For the numerical example corresponding to FIG. 7, our calculations show that a SMSR better than 20 dB can be obtained with a refractive index setting error corresponding to less than ±12.5% of the channel spacing. For optimal performance, an electronic feedback circuit can be implemented to stabilize the refractive index at the optimal channel setting point.

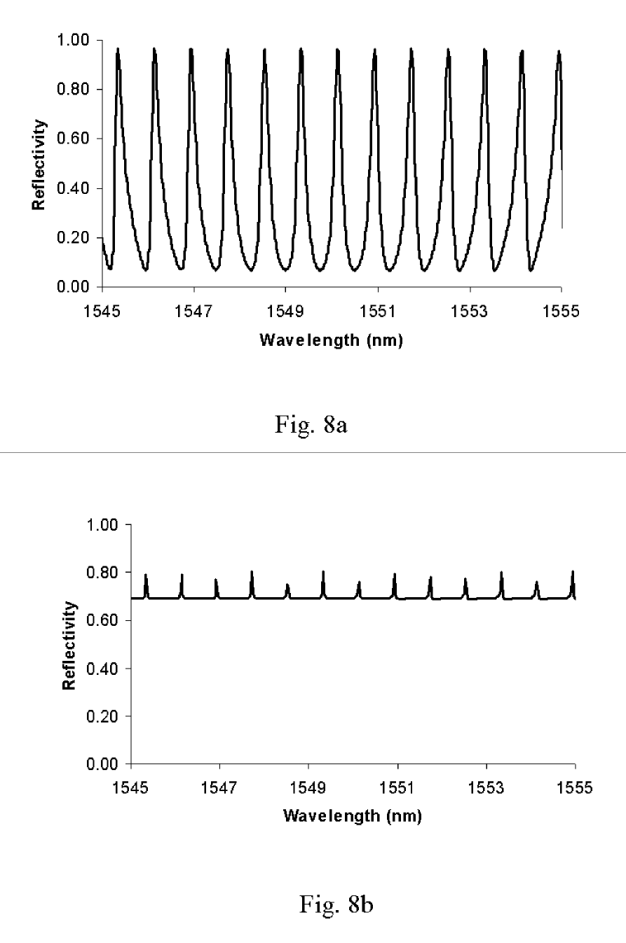

The mode selectivity, which relates to channel crosstalk or side-mode suppression ratio (SMSR), is an important consideration in the design of the device. The mode selectivity can be optimized by appropriately choosing a loss value in the coupling cavity. To illustrate the effect of the coupling cavity loss, we calculated the reflectivity spectra of the reflector comprising the coupling cavity and the wavelength selector cavity for different loss values of the coupling cavity. FIG. 8 shows the spectra for loss values of 1.23 dB and 12.3 dB. The corresponding lasing threshold of the combined structure is gₜₕ=13.8 cm⁻¹ and 15.9 cm⁻¹, respectively. In conjunction with FIG. 6 that corresponds to a coupling cavity loss of 4.9 dB, we can see that when the loss increases, the reflectivity peaks become narrower while the contrast decreases.

Since the discrimination of side modes is based on the misalignment of resonant modes between the fixed gain cavity and the channel selector cavity, the narrower the reflectivity peaks, the better the mode selectivity, especially for adjacent modes. However, as the reflectivity contrast decreases, the suppression ratio for distant modes decreases. Therefore, there exists an optimal loss value for the coupling cavity in order to achieve a good mode selectivity.

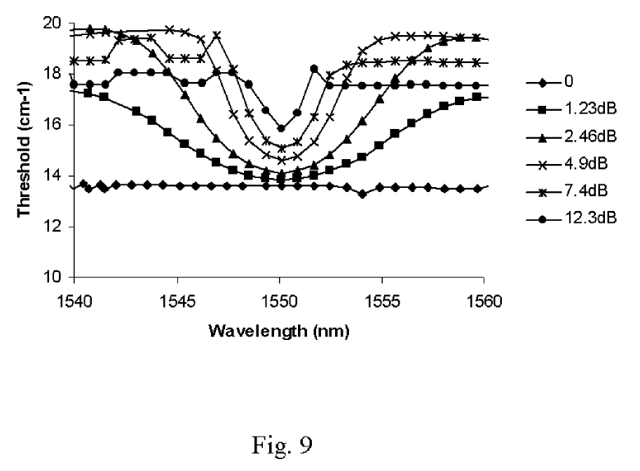

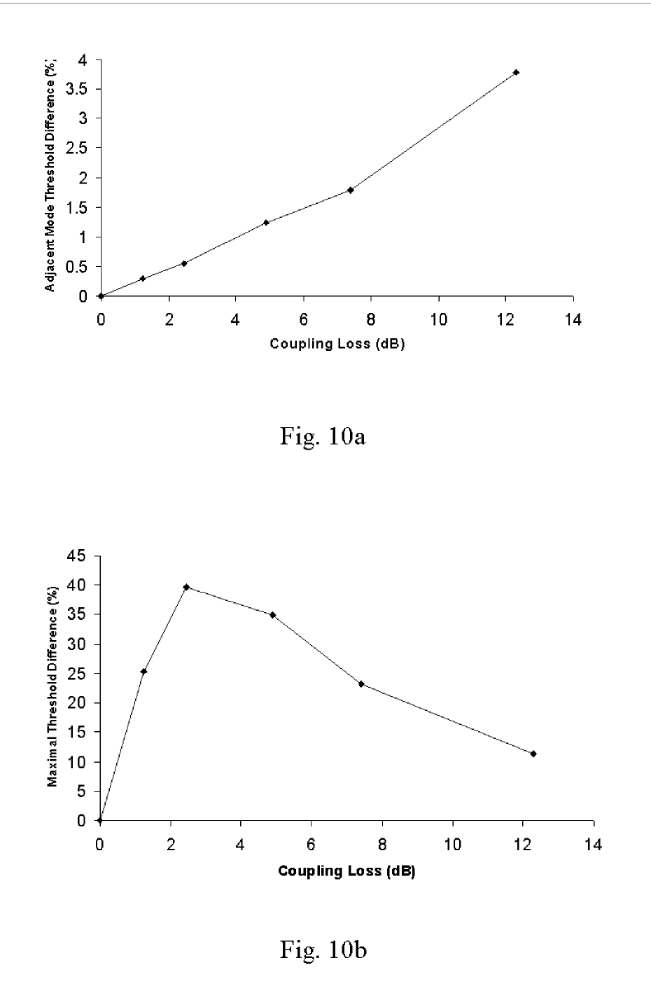

The mode selectivity can be characterized by threshold difference between the side modes and the main mode. FIG. 9 shows the thresholds of the lasing modes for different coupling cavity loss values of 0, 1.23 dB, 2.46 dB, 4.9 dB, 7.4 dB, and 12.3 dB. In FIG. 10, we plot the relative threshold difference between adjacent (a) and distant (b) modes as a function of the coupling cavity loss value. We can see that a loss value around 4.9 dB˜7.4 dB gives the best compromise considering both the adjacent and distant mode threshold differences.

The optimal loss value of the coupling cavity can be achieved by design or by post-fabrication adjustment. Since the optimal value can be affected by the quality of the fabrication such as the sidewall verticality and smoothness of the air gaps, the coupling cavity in the form of a variable attenuator is advantageous. This can be realized by applying a reverse-bias voltage on the waveguide in the coupling cavity.

By increasing the length difference between the fixed gain cavity and the channel selector cavity, the threshold difference between adjacent modes can be increased, at the expense of reduced free spectral range (as determined by Eq. (3)).

With the advancement of fabrication technologies, it can be expected that the minimum feature size of the air trenches will decrease over time. It is conceivable to replace the reflector comprising of the single air gap by a deep-etched grating with multiple air trenches. The reflectivity of the mirror will increase and the required coupling cavity loss decreases for obtaining high mode selectivity. The threshold of the combined cavity laser will also decrease.

Another possible variation of the design of the present invention is to employ an air gap as the coupling cavity. The size of the air gap is designed to be substantially equal to a multiple of half-wavelength, i.e. n″L″=m″λ/2, where the refractive index of the coupling cavity n″=1. The small integer m″ is chosen such that, for a given layer structure of the waveguide in the gain cavity and the wavelength selector cavity, the coupling loss caused by the beam divergence in the air gap provides an optimal loss value for the coupling cavity in order to achieve a good mode selectivity.

Numerous other embodiments can be envisaged without departing from the spirit and scope of the invention.

1. A monolithically integrated wavelength switchable laser comprising:
a first active optical cavity consisting of a first active waveguide bounded by two partially reflecting elements,
a second active optical cavity consisting of a second active waveguide bounded by two partially reflecting elements, said second active waveguide having a slightly different length than the first active waveguide,
a passive optical cavity placed between the first and the second active optical cavities, said passive optical cavity being coupled with each of the first and the second active optical cavity through a shared partially reflecting element,
whereas each of the first and the second active waveguides is sandwiched between at least a pair of electrodes for injecting current to provide optical gain, with the current injected into at least a portion of the second active waveguide being variable in order to change its refractive index and consequently to switch the laser wavelength between channels as determined by the resonant wavelengths of the first active optical cavity, and whereas the passive optical cavity introduces a certain optical loss in order to produce single-mode operation of the laser.

2. A monolithically integrated wavelength switchable laser as defined in claim 1, wherein the length difference between the first and the second active optical cavities is less than 10 percent.

3. A monolithically integrated wavelength switchable laser as defined in claim 1, wherein the passive optical cavity is coupled with each of the first and the second active optical cavities through an etched air gap.

4. A monolithically integrated wavelength switchable laser as defined in claim 3, wherein the air gap has vertically-etched sidewalls and is of a size that is substantially equal to an odd-integer multiple of quarter-wavelength.

5. A monolithically integrated wavelength switchable laser as defined in claim 1, wherein the optical path length of the passive optical cavity is substantially equal to a multiple of half-wavelength with the multiplication factor being a small integer.

6. A monolithically integrated wavelength switchable laser as defined in claim 5, wherein the multiplication factor is an integer less than 10.

7. A monolithically integrated wavelength switchable laser as defined in claim 5, wherein the passive optical cavity further comprises an optical waveguide, said optical waveguide being sandwiched between a pair of electrodes for providing an electrical means to vary the absorption of the waveguide.

8. A monolithically integrated wavelength switchable laser as defined in claim 1 wherein the length and consequently the free spectral range of the first active optical cavity are designed such that its resonant peaks correspond substantially to a set of discrete operating wavelengths separated by a constant channel spacing as defined by the ITU standard.
